(19) United States
(12) Patent Application Publication
(10) Pub. No.: US 2026/0123403 A1
(43) Pub. Date: Apr. 30, 2026

(54) SEMICONDUCTOR PACKAGE STRUCTURE AND METHOD FOR FORMING A SEMICONDUCTOR PACKAGE STRUCTURE

(71) Applicant: Taiwan Semiconductor Manufacturing Company, Ltd., Hsinchu (TW)

(72) Inventors: Chi-Shiang CHIOU, Hsinchu (TW); Hsien-Wei CHEN, Hsinchu City (TW)

(21) Appl. No.: 18/926,729

(22) Filed: Oct. 25, 2024

(51) Int. Cl. H01L 23/367; H01L 23/00; H01L 23/498; H01L 25/065

(52) U.S. Cl. CPC H10W 40/22; H10W 70/65; H10W 90/701; H10W 72/07254; H10W 72/242; H10W 90/00; H10W 90/726

(57) ABSTRACT

A semiconductor package structure includes a substrate, a redistribution layer, a first semiconductor die, a second semiconductor die, a first thermal interface material (TIM) film, a second TIM film, and a heat-dissipating lid. The redistribution layer is attached to the substrate. The first semiconductor die and the second semiconductor die are disposed over the redistribution layer. The first TIM film is formed over the first semiconductor die. The second TIM film is formed over the second semiconductor die. The heat-dissipating lid is attached to the substrate. The heat-dissipating lid has first regions with a first cavity depth and a second region with a second cavity depth. The second cavity depth is greater than the first cavity depth. The second TIM film is disposed in the second region of the heat-dissipating lid.

### BACKGROUND

Semiconductor devices are widely used in various electronic applications, such as personal computers, mobile phones, digital cameras, and other electronic equipment. As the size of semiconductor devices shrinks, the difficulty of manufacturing semiconductor devices has also increased significantly. Defects may occur during the process of manufacturing semiconductor devices, and these defects may cause failure, or they may cause the performance of the semiconductor devices to suffer. Therefore, further improvements in semiconductor devices are required.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A to 1G illustrate cross-sectional views of various stages of manufacturing a semiconductor package structure in accordance with some embodiments of the present disclosure.

FIG. 2 illustrates a top view of a semiconductor package structure in accordance with some embodiments of the present disclosure.

FIG. 3 illustrates a top view of a semiconductor package structure in accordance with some embodiments of the present disclosure.

FIG. 4 illustrates a cross-sectional view of a semiconductor package structure in accordance with some embodiments of the present disclosure.

FIG. 5 illustrates a top view of a semiconductor package structure in accordance with some embodiments of the present disclosure.

FIG. 6 illustrates a cross-sectional view of a semiconductor package structure in accordance with some embodiments of the present disclosure.

FIG. 7 illustrates a top view of a semiconductor package structure in accordance with some embodiments of the present disclosure.

FIG. 8 illustrates a cross-sectional view of a semiconductor package structure in accordance with some embodiments of the present disclosure.

FIG. 9 illustrates a cross-sectional view of a semiconductor package structure in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

Semiconductor package structures and methods for forming a semiconductor package structure are described in accordance with some embodiments of the present disclosure. The semiconductor package structure may include a chip-on-wafer-on-substrate (CoWoS) package structure. A thermal interface material (TIM) film is needed for the CoWoS package structure in high performance computing field. However, high stretch stress at edge of the package structure may cause cracks in the TIM film. The semiconductor package structure according to some embodiments of the present disclosure includes multiple discrete TIM films, at least one of which is thickened, so that the stress stretch flexibility can be improved and the crack propagation in the TIM films can be prevented. As a result, a better reliability performance especially in thermal cycle condition can be achieved.

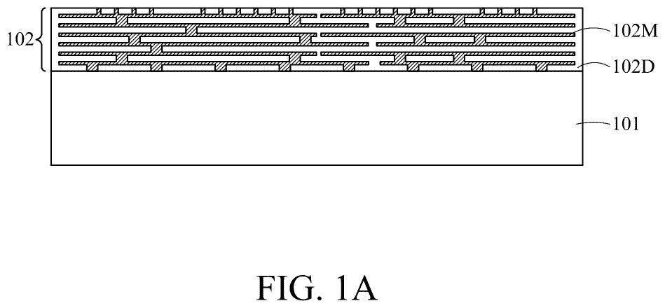

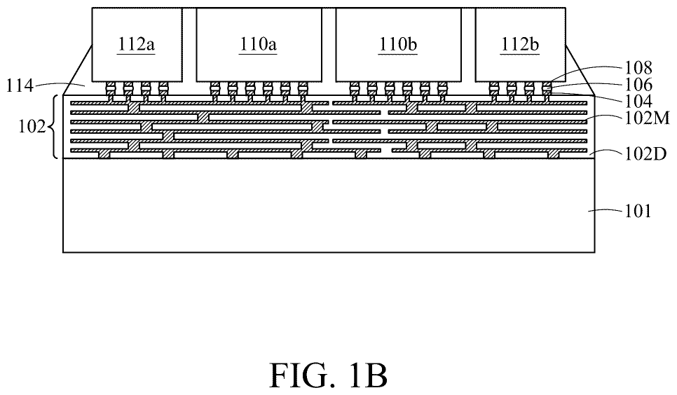

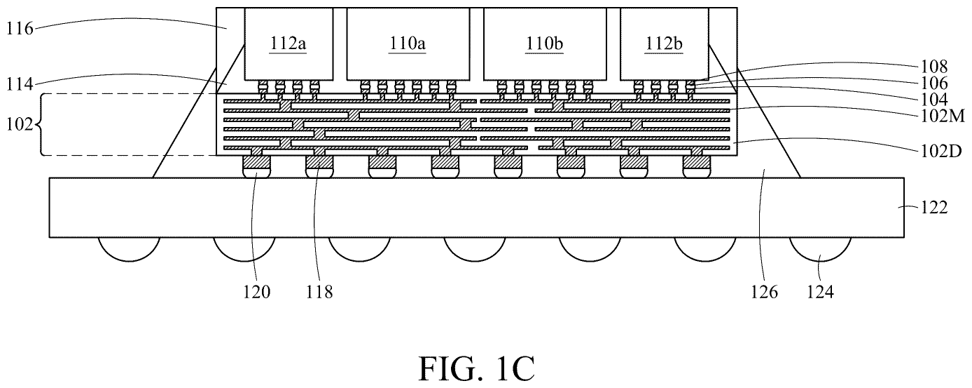

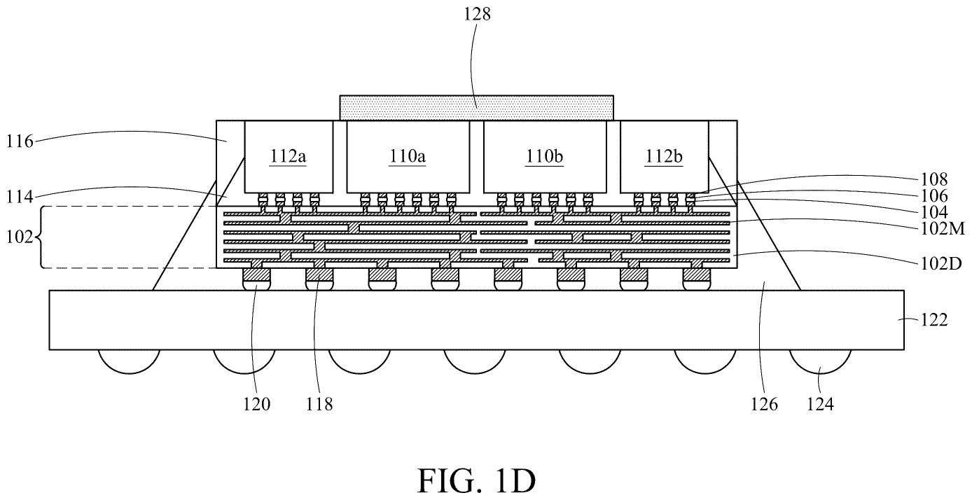

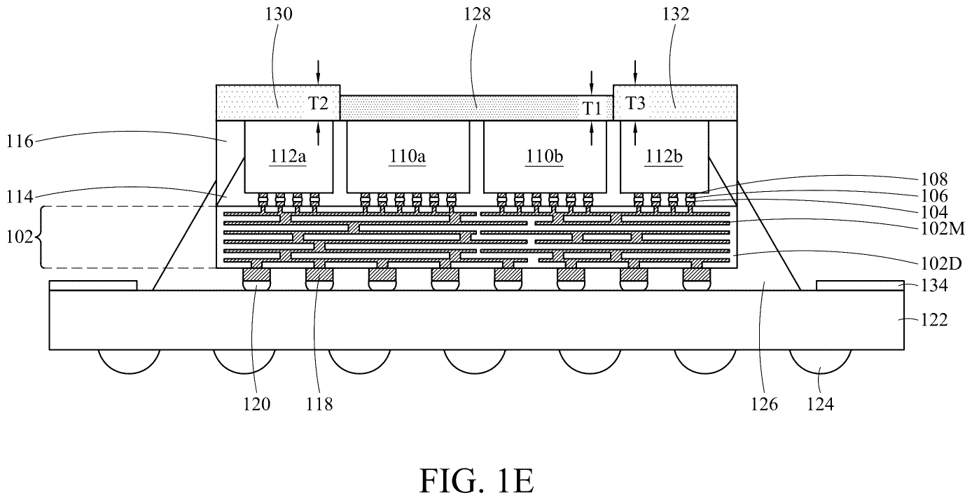

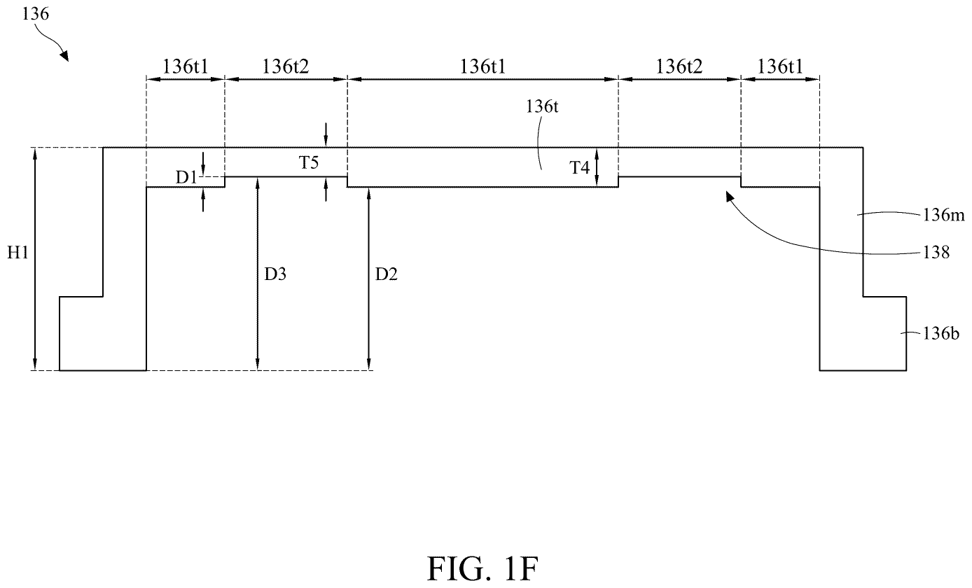

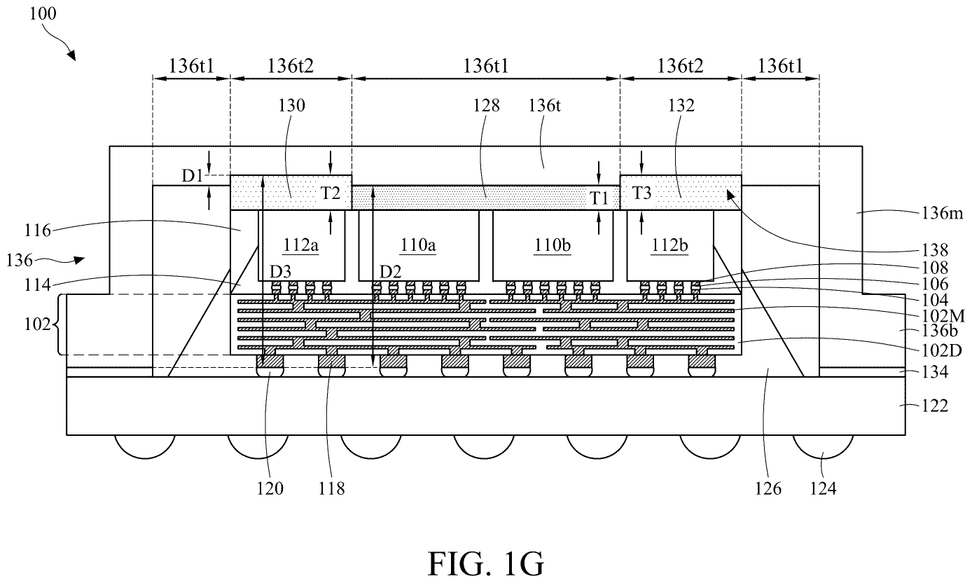

FIGS. 1A to 1G illustrate cross-sectional views of various stages of manufacturing a semiconductor package structure 100 in accordance with some embodiments of the present disclosure. Additional features can be added to the semiconductor package structure 100. Some of the features described below can be replaced or eliminated for different embodiments. To simplify the diagram, only a portion of the semiconductor package structure 100 is illustrated.

As illustrated in FIG. 1A, a redistribution layer 102 is formed over a carrier substrate 101, in accordance with some embodiments. The carrier substrate 101 may provide temporary mechanical and structural support during subsequent processing steps. The carrier substrate 101 may be made of glass, silicon, silicon oxide, aluminum oxide, metal, another suitable material, or a combination thereof.

The redistribution layer 102 may include an interconnect structure 102M disposed in one or more dielectric layers 102D. The redistribution layer 102 may be formed by repeatedly forming the dielectric layer 102D and each layer of the interconnect structure 102M over the carrier substrate 101. In particular, one of the dielectric layers 102D may be formed, followed by forming trenches and openings in the dielectric layer 102D, and then the material of the interconnect structure 102M may be filled in the trenches and openings.

The dielectric layers 102D may be formed of polymer, including polyimide (PI), polybenzoxazole (PBO), benzocyclobutene (BCB), epoxy, ceramic, the like, or a combination thereof. Alternatively, the dielectric layers 102D may be formed of non-organic materials, including silicon oxide, silicon nitride, silicon oxynitride, the like, or a combination thereof. The dielectric layer 102D may be formed by spin coating, chemical vapor deposition (CVD), another suitable deposition process, or a combination thereof.

The trenches and openings may be formed by using photolithography and etching process. The photolithography process may include photoresist coating (e.g., spin-on coating), soft baking, mask aligning, exposure, post-exposure baking, photoresist developing, rinsing, drying (e.g., spin-drying and/or hard baking), another suitable photolithography techniques, or a combination thereof. The etching process may include a dry etching (e.g., reactive ion etching (RIE) or anisotropic plasma etching) process, a wet etching process, or a combination thereof.

The interconnect structure 102M may include horizontal interconnects, such as conductive layers or conductive pads, and vertical interconnects, such as conductive vias. The conductive vias may electrically couple different levels of the conductive layers and the conductive pads. The interconnect structure 102M may be made of conductive material, such as metal, including tungsten, titanium, tantalum, ruthenium, cobalt, copper, aluminum, platinum, tin, silver, gold, the like, an alloy thereof, another suitable material, or a combination thereof. The interconnect structure 102M may be formed by plating, electroless plating, sputtering, chemical vapor deposition (CVD), another suitable process, or a combination thereof.

It should be noted that the number of layers of the dielectric layers 102D and the number of the interconnect structure 102M shown in FIG. 1A are for illustrative purposes only, and the present disclosure is not limited thereto.

Then, as illustrated in FIG. 1B, a plurality of conductive pads 104 are formed on the surface of the redistribution layer 102 and electrically coupled to the interconnect structure 102M. The conductive pads 104 may be formed of conductive material, such as metal, including tungsten, titanium, tantalum, ruthenium, cobalt, copper, aluminum, platinum, tin, silver, gold, an alloy thereof, another suitable material, or a combination thereof. The conductive pads 104 may be formed by an electroplating process, an electroless plating process, a sputtering process, a CVD process, another suitable process, or a combination thereof.

A plurality of conductive connectors 106 are formed over the conductive pads 104, in accordance with some embodiments. The conductive connectors 106 may include microbumps, controlled collapse chip connection (C4) bumps, solder balls, ball grid array (BGA) balls, another suitable component, or a combination thereof. The conductive connectors 106 may be formed of conductive material, such as metal, including tungsten, titanium, tantalum, ruthenium, cobalt, copper, aluminum, platinum, tin, silver, gold, an alloy thereof, another suitable material, or a combination thereof.

A plurality of conductive pads 108 are formed under a plurality of semiconductor dies 110a, 110b, 112a, and 112b, in accordance with some embodiments. The semiconductor dies 110a, 110b, 112a, and 112b may be jointed to the redistribution layer 102 through the conductive pads 104, the conductive connectors 106, and the conductive pads 108. The conductive pads 108 may be formed of conductive material, such as metal, including tungsten, titanium, tantalum, ruthenium, cobalt, copper, aluminum, platinum, tin, silver, gold, an alloy thereof, another suitable material, or a combination thereof. The conductive pads 108 may be formed by an electroplating process, an electroless plating process, a sputtering process, a CVD process, another suitable process, or a combination thereof.

In some embodiments, the semiconductor dies 110a, 110b, 112a, and 112b each independently includes a system-on-chip (SoC) die, a logic device, a memory device, a radio frequency (RF) device, another suitable device, or a combination thereof. For example, the semiconductor dies 110a, 110b, 112a, and 112b may each include a micro control unit (MCU) die, a microprocessor unit (MPU) die, a power management integrated circuit (PMIC) die, a radio frequency front end (RFFE) die, an accelerated processing unit (APU) die, a central processing unit (CPU) die, a graphics processing unit (GPU) die, an input-output (IO) die, a dynamic random access memory (DRAM) controller, a static random-access memory (SRAM) die, a high bandwidth memory (HBM) die, an application processor (AP) die, an application specific integrated circuit (ASIC) die, another suitable device, or a combination thereof.

The semiconductor dies 110a, 110b, 112a, and 112b may include the same or different devices. For example, the semiconductor dies 110a and 110b may include SoC dies and the semiconductor dies 112a and 112b may include HBM dies. It should be noted that the number of semiconductor dies is for illustrative purposes only, and more or fewer semiconductor dies and/or one or more passive components (such as resistors, capacitors, or inductors) may be disposed over the redistribution layer 102.

The semiconductor dies 110a, 110b, 112a, and 112b may be bonded onto the redistribution layer 102 by reflowing or another suitable bonding process. The thicknesses of the semiconductor dies 110a, 110b, 112a, and 112b may be substantially the same in a direction that is substantially perpendicular to the top surface of the redistribution layer 102.

Next, an underfill material 114 is formed over the redistribution layer 102, in accordance with some embodiments. The underfill material 114 may surround each of the conductive pads 104, the conductive connectors 106, and the conductive pads 108 to provide structural support and protection to the active circuitry from the environment. The underfill material 114 may extend on the sidewalls of the semiconductor dies 110a, 110b, 112a, and 112b.

The underfill material 114 may be made of polymer, including epoxy, polyimide, polybenzoxazole (PBO), another suitable material, or a combination thereof. The underfill material 114 may be dispensed with capillary force, and then may be cured through a curing process, including a thermal curing process, an infrared (IR) energy curing process, an ultraviolet (UV) curing process, another suitable process, or a combination thereof.

Then, as illustrated in FIG. 1C, a molding material 116 is formed over the redistribution layer 102, in accordance with some embodiments. The molding material 116 may surround the semiconductor dies 110a, 110b, 112a, 112b and the underfill material 114 to protect these components from the environment, thereby preventing them from damage due to stress, chemicals, and moisture. The molding material 116 may be formed of a non-conductive material, including moldable polymer, epoxy, resin, the like, or a combination thereof.

In some embodiments, the underfill material 114 extends to the top surfaces of the semiconductor dies 110a, 110b, 112a, and 112b, as illustrated in FIG. 1C. In some other embodiments, the top surface of the underfill material 114 is below the top surfaces of the semiconductor dies 110a, 110b, 112a, and 112b, and the molding material 116 extends over the underfill material 114 and to the top surfaces of the semiconductor dies 110a, 110b, 112a, and 112b.

Then, a planarization process may be performed on the molding material 116 until the top surfaces of the semiconductor dies 110a, 110b, 112a, and 112b are exposed. The planarization process may include a chemical mechanical planarization (CMP) process, a mechanical grinding process, a dry polishing process, an etching process, another suitable process, or a combination thereof. The top surface of the semiconductor dies 110a, 110b, 112a, and 112b, and the molding material 116 may be substantially aligned with each other.

Afterwards, the carrier substrate 101 is removed, in accordance with some embodiments of the present disclosure. The carrier substrate 101 may be removed by a de-bonding process or another suitable process. A portion of the redistribution layer 102 may be removed to expose the interconnect structure 102M.

Then, a plurality of the conductive pads 118 are formed under the redistribution layer 102 and electrically coupled to the interconnect structure 102M, in accordance with some embodiments of the present disclosure. The conductive pads 118 may be formed of conductive material, such as metal, including tungsten, titanium, tantalum, ruthenium, cobalt, copper, aluminum, platinum, tin, silver, gold, an alloy thereof, another suitable material, or a combination thereof. The conductive pads 118 may be formed by an electroplating process, an electroless plating process, a sputtering process, a CVD process, another suitable process, or a combination thereof.

Next, a plurality of the conductive connectors 120 are formed under the conductive pads 118, in accordance with some embodiments of the present disclosure. The conductive connectors 120 may include microbumps, controlled collapse chip connection (C4) bumps, solder balls, ball grid array (BGA) balls, another suitable components, or a combination thereof. The conductive connectors 120 may be formed of conductive material, such as metal, including tungsten, titanium, tantalum, ruthenium, cobalt, copper, aluminum, platinum, tin, silver, gold, an alloy thereof, another suitable material, or a combination thereof.

Afterwards, the redistribution layer 102 is mounted onto a package substrate 122 through the conductive connectors 120, in accordance with some embodiments of the present disclosure. The package substrate 122 may provide electrical connection between semiconductor devices packaged and an external electronic device.

The package substrate 122 may be a coreless substrate or may include an insulating core, such as a fiberglass reinforced resin core, to prevent the package substrate 122 from warpage. The package substrate 122 may be a printed circuit board (PCB), a ceramic substrate, or another suitable package substrate. The package substrate 122 may include one or more layers of electrically-conductive traces. Any desired semiconductor element may be formed in and on the package substrate 122. However, in order to simplify the diagram, only the flat package substrate 122 is illustrated.

Then, an underfill material 126 is formed over the package substrate 122, in accordance with some embodiments. The underfill material 126 may surround each of the conductive pads 118, the conductive connectors 120, and the redistribution layer 102 to provide structural support and protection to the active circuitry from the environment. The underfill material 126 may extend on sidewalls of the molding material 116. The material and formation of the underfill material 126 may be similar to that of the underfill material 114, and will not be repeated.

A plurality of the conductive terminals 124 are formed under the package substrate 122, in accordance with some embodiments of the present disclosure. The conductive terminals 124 may include microbumps, controlled collapse chip connection (C4) bumps, solder balls, ball grid array (BGA) balls, another suitable components, or a combination thereof. The conductive terminals 124 may be formed of conductive material, such as metal, including tungsten, titanium, tantalum, ruthenium, cobalt, copper, aluminum, platinum, tin, silver, gold, an alloy thereof, another suitable material, or a combination thereof.

Then, as illustrated in FIG. 1D, a thermal interface material (TIM) film 128 is formed covering the underfill material 114 and the semiconductor dies 110a and 110b, in accordance with some embodiments. The TIM film 128 may be a thermally conductive material. The TIM film 128 may be formed of a solid material, including graphite or another suitable material. In some embodiments, the TIM film 128 is a graphite sheet mixed with organic polymer or resin to improve the TIM film adhesive strength to prevent it from cracking. For example, the TIM film 128 may include a graphite sheet mixed with organic material such as polybutene, resin, or another suitable material. The graphite sheet used as the TIM film 128 may have a higher thermal conductivity than resin, and may be flexible in order to facilitate the subsequent attaching process.

The top surfaces of the semiconductor dies 110a and 110b are in direct contact with the TIM film 128. Therefore, the heat generated in the semiconductor dies 110a and 110b may be well conducted to the subsequently formed heat-dissipating lid. In some embodiments, the TIM film 128 extends beyond the sidewalls of the semiconductor dies 110a and 110b. In these embodiments, the sidewalls of the TIM film 128 are in direct contact with the underfill material 114, or in direct contact with the molding material 116 when the top surface of the underfill material 114 is lower than the top surfaces of the semiconductor dies 110a and 110b.

Then, as illustrated in FIG. 1E, a plurality of thickened TIM films 130 and 132 are formed covering the underfill material 114, the molding material 116, and the semiconductor dies 112a and 112b, in accordance with some embodiments. The material of the thickened TIM films 130 and 132 may include a graphite sheet mixed with organic material such as polybutene, resin, or another suitable material. The graphite sheet used as the thickened TIM films 130 and 132 may have a better adhesive strength for TIM edge crack improvement. In some embodiments, the TIM film 128 and the thickened TIM films 130 and 132 are made of the same material. In some embodiments, the TIM film 128 and the thickened TIM films 130 and 132 are made of different materials. In some embodiments, both the TIM film 128 and the thickened TIM films 130 and 132 include a graphite sheet, but the mixing ratio of graphite sheet and organic material may be different. For example, the mixing ratio of graphite sheet in the TIM film 128 may be higher than that in the thickened TIM films 130 and 132. The top surfaces of the semiconductor dies 112a and 112b are in direct contact with the thickened TIM films 130 and 132, respectively. Therefore, the heat generated in the semiconductor dies 112a and 112b may be well conducted to the subsequently formed heat-dissipating lid.

The TIM film 128 may have a thickness T1, the thickened TIM film 130 may have a thickness T2, and the thickened TIM film 132 may have a thickness T3 in a direction that is substantially perpendicular to the top surface of the redistribution layer 102. The thickness T2 of the thickened TIM film 130 may be greater than the thickness T1 of the TIM film 128. The thickness T3 of the thickened TIM film 132 may be greater than the thickness T1 of the TIM film 128. With separating one piece TIM film into at least two pieces of TIM films and increasing the thicknesses of the TIM films in periphery of the redistribution layer 102 (including the thickened TIM films 130 and 132), better stress stretch flexibility and TIM film crack prevention can be achieved.

The thickness T1 of the TIM film 128 may be in a range of about 20 μm to about 150 μm. The thickness T2 of the thickened TIM film 130 may be in a range of about 20.1μm to about 320 μm. The thickness T3 of the thickened TIM film 132 may be in a range of about 20.1 μm to about 320 μm. The thickness T3 of the thickened TIM film 132 may be substantially equal to the thickness T2 of the thickened TIM film 130. The difference between the thickness T2 of the thickened TIM film 130 and the thickness T1 of the TIM film 128 may be in a range of about 0.1 to about 300 μm. The difference between the thickness T3 of the thickened TIM film 132 and the thickness T1 of the TIM film 128 may be in a range of about 0.1 to about 300 μm.

The interface between the TIM film 128 and the thickened TIM film 130 may be disposed directly above the gap between the semiconductor dies 110a and 112a. The interface between the TIM film 128 and the thickened TIM film 132 may be disposed directly above the gap between the semiconductor dies 110b and 112b. Pores or another defects may be formed at the interface, which are unfavorable to heat dissipation. In consequence, disposing these interfaces outside the semiconductor dies 110a, 110b, 112a, 112b can further improve the heat dissipation.

The top surface of the TIM film 128 may be lower than the top surfaces of the thickened TIM films 130 and 132. The bottom surface of the TIM film 128 and the bottom surfaces of the thickened TIM films 130 and 132 may be substantially aligned with each other.

In some embodiments, the thickened TIM film 130 covers the entire top surface of the semiconductor dies 112a, and the thickened TIM film 132 covers the entire top surface of the semiconductor dies 112b. In particular, the thickened TIM film 130 may extend beyond opposite sidewalls of the semiconductor dies 112a and the thickened TIM film 132 may extend beyond opposite sidewalls of the semiconductor dies 112b. In these embodiments, a sidewall of the thickened TIM film 130 and a sidewall of the thickened TIM film 132 are directly over and in direct contact with the underfill material 114 (or the molding material 116 when the top surface of the underfill material 114 is lower than the top surfaces of the semiconductor dies 110a and 110b). The sidewalls of the molding material 116 may be substantially aligned with another sidewall of the thickened TIM film 130 and another sidewall of the thickened TIM film 132, respectively.

Then, an adhesive layer 134 is formed over the package substrate 122, in accordance with some embodiments. The adhesive layer 134 may be disposed over the periphery of the package substrate 122. The adhesive layer 134 may allow the subsequently formed heat-dissipating lid attached to the package substrate 122. The adhesive layer 134 may be made of epoxy, silicon resin, die attach film (DAF), another suitable material, or a combination thereof.

Then, as illustrated in FIG. 1F, a heat-dissipating lid 136 is provided, in accordance with some embodiments. The heat-dissipating lid 136 may have different cavity depths. The heat-dissipating lid 136 with the cavity depths may be formed by mold casting, drilling, or another suitable method. The cavity depth may be the distance between the two bottom surfaces of the heat-dissipating lid 136.

The heat-dissipating lid 136 may include a bottom portion 136b, a middle portion 136m, and a top portion 136t. The middle portion 136m may connect the bottom portion 136b and the top portion 136t. Alternatively, the bottom portion 136b and the middle portion 136m may be collectively referred to as a footing portion, and the top portion 136t may be referred to as a board portion. That is, the heat-dissipating lid 136 may include the footing portion 136b and 136m and the board portion 136t connected to the footing portion 136b and 136m.

The top portion 136t of the heat-dissipating lid 136 may have a thickness T4 in regions 136t1 and a thickness T5 in regions 136t2 in a direction that is substantially perpendicular to the top surface of the heat-dissipating lid 136. The thickness T4 may be greater than the thickness T5. Some of the regions 136t1 may be at periphery of the heat-dissipating lid 136, and one of the regions 136t1 may be at center of the heat-dissipating lid 136. Two of the regions 136t1 may be separated by one of the regions 136t2.

The top portion 136t of the heat-dissipating lid 136 may have a plurality of recesses 138 in the regions 136t2. Each of the recesses 138 may have a depth D1 in a direction that is substantially perpendicular to the top surface of the heat-dissipating lid 136. The depth D1 may be in a range of about 0.1 μm to about 300 μm.

The heat-dissipating lid 136 may have a cavity depth D2 in the regions 136t1 in a direction that is substantially perpendicular to the top surface of the heat-dissipating lid 136. The cavity depth D2 may be the distance between the lower bottom surface of the top portion 136t and the bottommost surface (i.e. the bottom surface of the bottom portion 136b) of the heat-dissipating lid 136. The heat-dissipating lid 136 may have a cavity depth D3 in the regions 136t2 in a direction that is substantially perpendicular to the top surface of the heat-dissipating lid 136. The cavity depth D3 may be the distance between the upper bottom surface of the top portion 136t and the bottommost surface of the heat-dissipating lid 136.

The cavity depth D3 may be greater than the cavity depth D2. In some embodiments, the cavity depth D2 is in a range of about 600 μm to about 999.9 μm. In some embodiments, the cavity depth D3 is in a range of about 600.1 μm to about 1000 μm. The difference between the cavity depth D3 and the cavity D2 may be substantially equal to the depth D1 of the recess 138.

The heat-dissipating lid 136 may have a height H1 in a direction that is substantially perpendicular to the top surface of the heat-dissipating lid 136. The height H1 may be the distance between the topmost surface (i.e. the top surface of the top portion 136t) and the bottommost surface of the heat-dissipating lid 136. The height H1 may be in a range of about 2.8 mm to about 3 mm.

Then, as illustrated in FIG. 1G, the heat-dissipating lid 136 is attached to the package substrate 122 through the adhesive layer 134, in accordance with some embodiments. The semiconductor package structure 100 is formed. The adhesive layer 134 may be applied over the top surface of the package substrate 122 before attaching as illustrated. Alternatively, the adhesive layer 134 may be applied to the bottom surface of the heat-dissipating lid 136 before attaching. The adhesive layer 126 may be in direct contact with the package substrate 122 and the heat-dissipating lid 136. The adhesive layer 126 may be spaced apart from the underfill material 126.

The TIM film 128 and the thickened TIM films 130 and 132 may be in direct contact with the top portion 136t of the heat-dissipating lid 136. The thickened TIM films 130 and 132 may be disposed in the regions 136t2, and the TIM film 128 may be disposed in the region 136t1 between the regions 136t2. The regions 136t2 may be at periphery of the redistribution layer 102, and the region 136t1 may be at center of the redistribution layer 102. The thickened TIM films 130 and 132 may partially extend into the top portion 136t of the heat-dissipating lid 136, and the TIM film 128 may be disposed below the top portion 136t of the heat-dissipating lid 136.

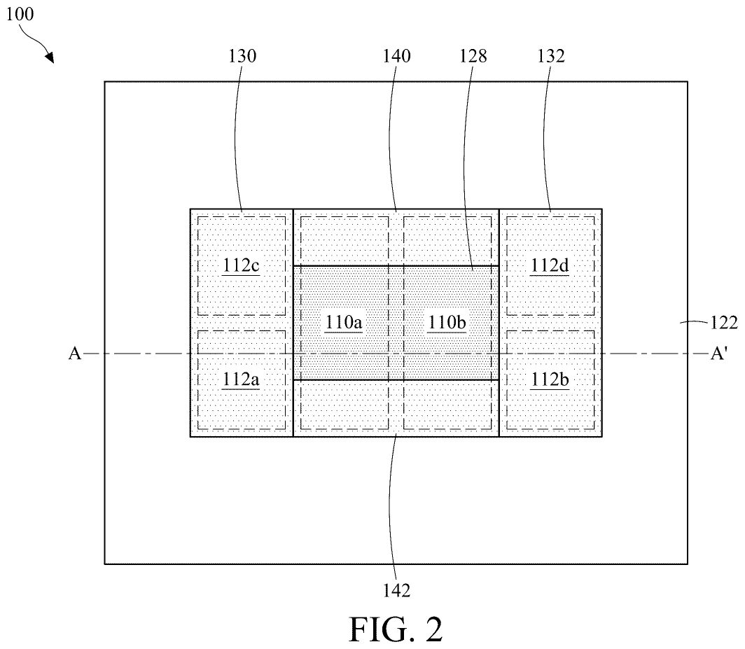

FIG. 2 illustrates a top view of the semiconductor package structure 100 of FIG. 1G, in accordance with some embodiments of the present disclosure. FIG. 1G is a cross-sectional view of the semiconductor package structure 100 taken along line A-A′ shown in FIG. 2.

As illustrated in FIG. 2, the semiconductor package structure 100 also includes semiconductor dies 112c and 112d adjacent to the semiconductor dies 110a and 110b, respectively, in accordance with some embodiments. The semiconductor dies 112c and 112d may include the components discussed above with respect to the semiconductor dies 110a, 110b, 112a, or 112b, and will not be described in detail.

The semiconductor dies 110a, 110b, 112a, 112b, 112c, and 112d may include the same or different devices. For example, the semiconductor dies 110a and 110b may include SoC dies and the semiconductor dies 112a, 112b, 112c, and 112d may include HBM dies. It should be noted that the number of semiconductor dies is for illustrative purposes only, and more or fewer semiconductor dies and/or one or more passive components (such as resistors, capacitors, or inductors) may be disposed over the package substrate 122.

The thickened TIM film 130 may cover the semiconductor dies 112a and 112c. The thickened TIM film 132 may cover the semiconductor dies 112b and 112d. The semiconductor package structure 100 also includes thickened TIM films 140 and 142 disposed over the semiconductor dies 110a and 110b, in accordance with some embodiments. The material of the thickened TIM films 140 and 142 may be similar to that of the TIM films 128, 130, or 132, and will not be repeated. The top surfaces of the semiconductor dies 110a and 110b may be in direct contact with the thickened TIM films 140 and 142, so that the heat generated in the semiconductor dies 110a and 110b may be well conducted to the heat-dissipating lid 136 (shown in FIG. 1G).

The thickness of the thickened TIM film 140 may be greater than the thickness of the TIM film 128. The thickness of the thickened TIM film 142 may be greater than the thickness of the TIM film 128. As a result, the TIM film 128 may be surrounded by thicker TIM films, including the thickened TIM films 130, 132, 140, and 142. Therefore, better stress stretch flexibility and TIM film crack prevention can be achieved.

As illustrated in FIG. 2, the interface between the TIM film 128 and the thickened TIM film 140 may cross the top surfaces of the semiconductor dies 110a and 110b. The interface between the TIM film 128 and the thickened TIM film 142 may cross the top surfaces of the semiconductor dies 110a and 110b.

In some embodiments, the thickened TIM film 140 extends beyond the sidewalls of the semiconductor dies 110a and 110b, and the thickened TIM film 142 extends beyond the sidewalls of the semiconductor dies 110a and 110b. The interface between the thickened TIM films 130 and 140 may be disposed directly above the gap between the semiconductor dies 110a and 112c. The interface between the thickened TIM films 132 and 140 may be disposed directly above the gap between the semiconductor dies 110b and 112d. The interface between the thickened TIM films 130 and 142 may be disposed directly above the gap between the semiconductor dies 110a and 112a. The interface between the thickened TIM films 132 and 142 may be disposed directly above the gap between the semiconductor dies 110b and 112b. By disposing the interfaces outside the semiconductor dies 110a, 110b, 112a, 112b, 112c, and 112d, the efficiency of heat dissipation can be further increased.

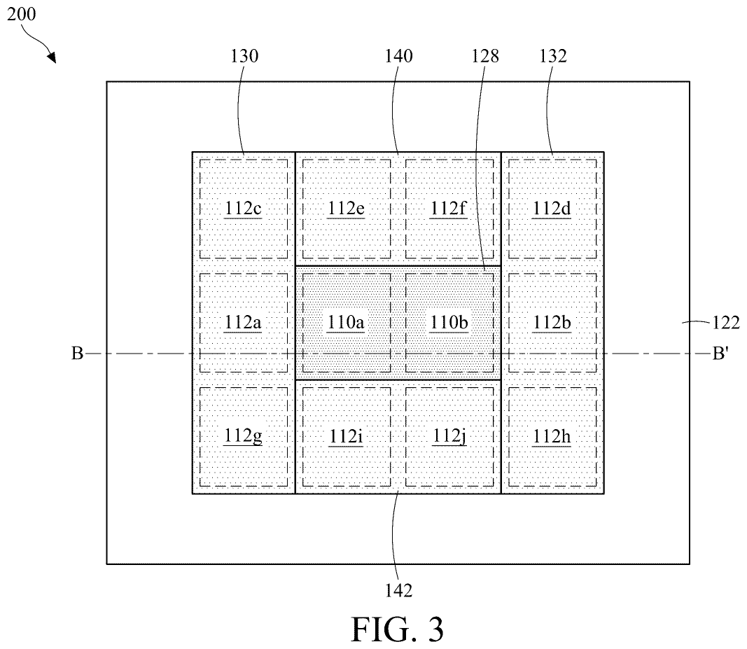

FIG. 3 illustrates a top view of a semiconductor package structure 200 in accordance with some other embodiments of the present disclosure. FIG. 1G may be a cross-sectional view of the semiconductor package structure 200 taken along line B-B′ shown in FIG. 3. The semiconductor package structure 200 in FIG. 3 may include the same or similar components as those of the semiconductor package structure 100 in FIG. 2, and for the sake of simplicity, those components will not be discussed in detail again. In the following embodiments, the semiconductor package structure 200 includes additional semiconductor dies.

As illustrated in FIG. 3, the semiconductor package structure 200 also includes semiconductor dies 112c, 112d, 112e, 112f, and semiconductor dies 112g, 112h, 112i, 112j on opposite sides of the semiconductor dies 110a and 110b, in accordance with some embodiments. The semiconductor dies 112c, 112d, 112e, 112f, 112g, 112h, 112i, and 112j may include the components discussed above with respect to the semiconductor dies 110a, 110b, 112a, or 112b, and will not be described in detail.

The semiconductor dies 110a, 110b, 112a, 112b, 112c, 112d, 112e, 112f, 112g, 112h, 112i, and 112j may include the same or different devices. For example, the semiconductor dies 110a and 110b may include SoC dies and the semiconductor dies 112a, 112b, 112c, 112d, 112e, 112f, 112g, 112h, 112i, and 112j may include HBM dies. It should be noted that the number of semiconductor dies is for illustrative purposes only, and more or fewer semiconductor dies and/or one or more passive components (such as resistors, capacitors, or inductors) may be disposed over the package substrate 122.

The thickened TIM film 130 may cover the semiconductor dies 112a, 112c, and 112g. The thickened TIM film 132 may cover the semiconductor dies 112b, 112d, and 112h. The semiconductor package structure 200 also includes a thickened TIM film 140 disposed over the semiconductor dies 112e and 112f and a thickened TIM film 142 disposed over the semiconductor dies 112i and 112j, in accordance with some embodiments.

The material of the thickened TIM films 140 and 142 may be similar to that of the TIM films 128, 130, or 132, and will not be repeated. The top surfaces of the semiconductor dies 112e and 112f may be in direct contact with the thickened TIM film 140 and the top surfaces of the semiconductor dies 112i and 112j may be in direct contact with the thickened TIM film 142, so that the heat generated in these semiconductor dies may be well conducted to the heat-dissipating lid 136 (shown in FIG. 1G).

The thickness of the thickened TIM film 140 may be greater than the thickness of the TIM film 128. The thickness of the thickened TIM film 142 may be greater than the thickness of the TIM film 128. As a result, the TIM film 128 may be surrounded by thicker TIM films, including the thickened TIM films 130, 132, 140, and 142. Therefore, better stress stretch flexibility and TIM film crack prevention can be achieved.

The interface between the TIM film 128 and the thickened TIM film 140 may be disposed directly above the gap between the semiconductor dies 110a and 112e and between the semiconductor dies 110b and 112f. The interface between the TIM film 128 and the thickened TIM film 142 may be disposed directly above the gap between the semiconductor dies 110a and 112i and between the semiconductor dies 110b and 112j. The interface between the thickened TIM films 130 and 140 may be disposed directly above the gap between the semiconductor dies 112c and 112e. The interface between the thickened TIM films 132 and 140 may be disposed directly above the gap between the semiconductor dies 112f and 112d. The interface between the thickened TIM films 130 and 142 may be disposed directly above the gap between the semiconductor dies 112g and 112i. The interface between the thickened TIM films 132 and 142 may be disposed directly above the gap between the semiconductor dies 112j and 112h. By disposing the interfaces outside the semiconductor dies 110a, 110b, 112a, 112b, 112c, 112d, 112e, 112f, 112g, 112h, 112i, and 112j, the efficiency of heat dissipation can be further increased.

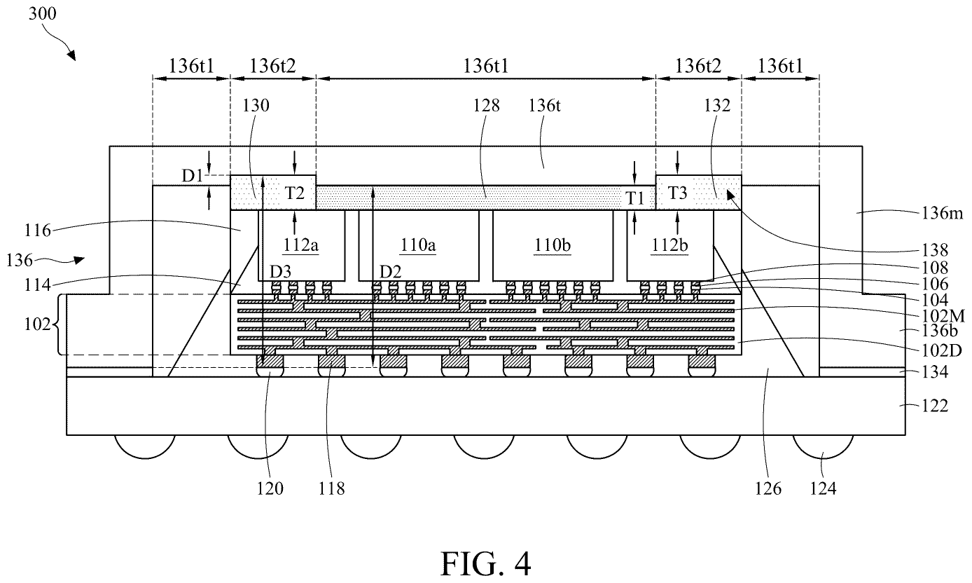

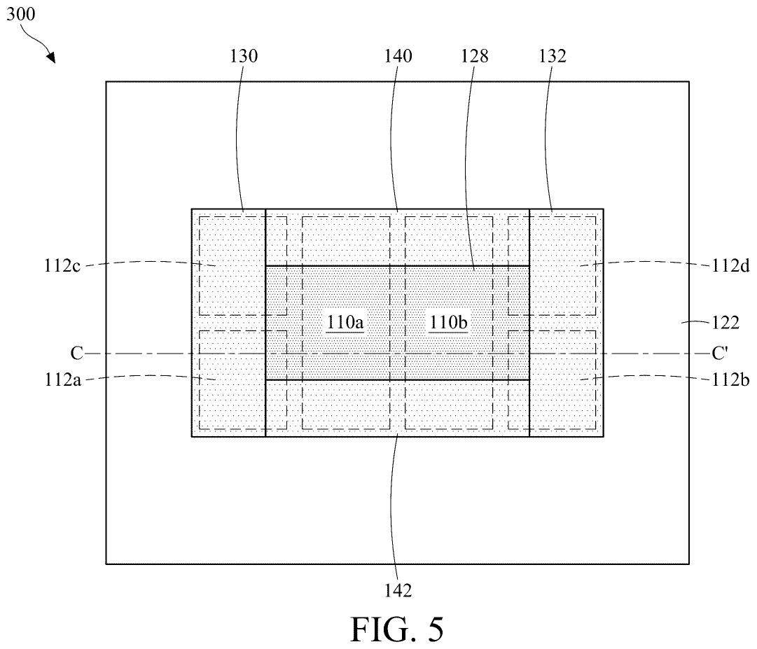

FIG. 4 illustrates a cross-sectional view of a semiconductor package structure 300 in accordance with some embodiments of the present disclosure. FIG. 5 illustrates a top view of the semiconductor package structure 300 of FIG. 4, in accordance with some embodiments of the present disclosure. FIG. 4 is a cross-sectional view of the semiconductor package structure 300 taken along line C-C′ shown in FIG. 5. It should be noted that the semiconductor package structure 300 may include the same or similar components as those of the semiconductor package structure 100, which is illustrated in FIGS. 1G and 2, and for the sake of simplicity, those components will not be discussed in detail again. In the following embodiments, the TIM film 128 extends above the semiconductor dies 112a and 112b.

As illustrated in FIG. 4, the sidewall of the TIM film 128 and the sidewall of the thickened TIM film 130 may be directly over and in contact with the top surface of the semiconductor die 112a. The sidewall of the TIM film 128 and the sidewall of the thickened TIM film 132 may be directly over and in contact with the top surface of the semiconductor dies 112b.

As illustrated in FIG. 5, the interface between the TIM film 128 and the thickened TIM film 130 may cross the semiconductor dies 112a and 112c. The interface between the TIM film 128 and the thickened TIM film 132 may cross the semiconductor dies 112b and 112d. The thickened TIM films 130, 132, 140, and 142 may surround the TIM film 128 to achieve better stress stretch flexibility and TIM film crack prevention.

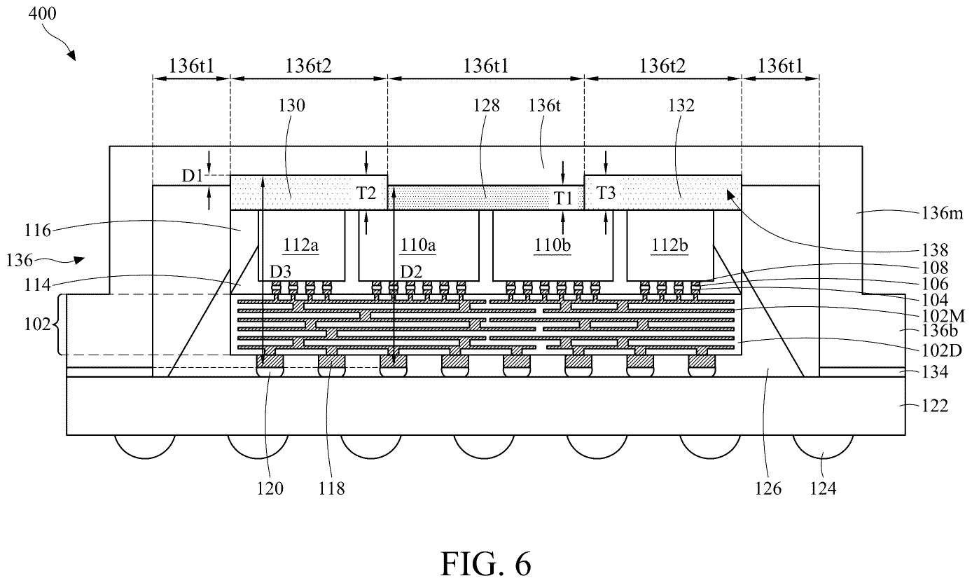

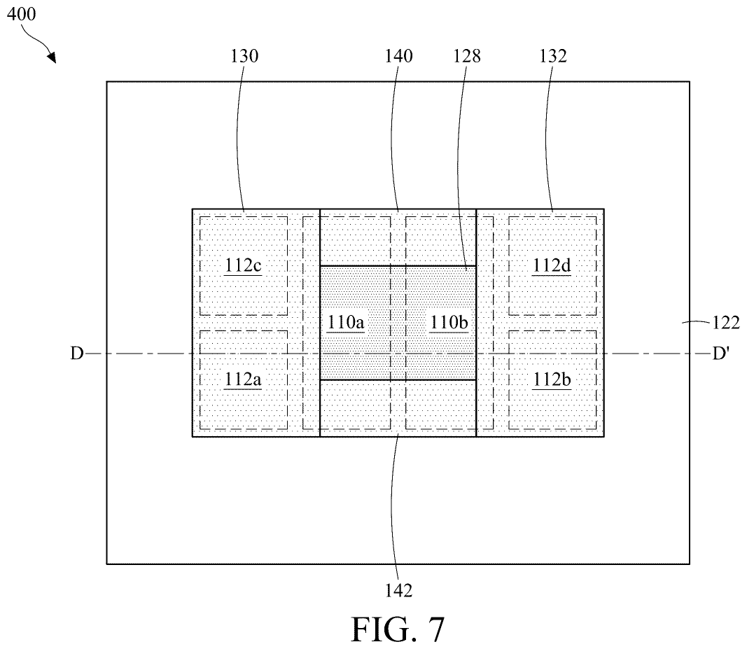

FIG. 6 illustrates a cross-sectional view of a semiconductor package structure 400 in accordance with some embodiments of the present disclosure. FIG. 7 illustrates a top view of the semiconductor package structure 400 of FIG. 6, in accordance with some embodiments of the present disclosure. FIG. 6 is a cross-sectional view of the semiconductor package structure 400 taken along line D-D′ shown in FIG. 7. It should be noted that the semiconductor package structure 400 may include the same or similar components as those of the semiconductor package structure 100, which is illustrated in FIGS. 1G and 2, and for the sake of simplicity, those components will not be discussed in detail again. In the following embodiments, the thickened TIM films 130 and 132 extend above the semiconductor dies 110a and 110b.

As illustrated in FIG. 6, the sidewall of the TIM film 128 and the sidewall of the thickened TIM film 130 may be directly over and in contact with the top surface of the semiconductor die 110a. The sidewall of the TIM film 128 and the sidewall of the thickened TIM film 132 may be directly over and in contact with the top surface of the semiconductor dies 110b.

As illustrated in FIG. 7, the interface between the TIM film 128 and the thickened TIM film 130 may cross the semiconductor die 110a. The interface between the TIM film 128 and the thickened TIM film 132 may cross the semiconductor die 110b. The thickened TIM films 130, 132, 140, and 142 may surround the TIM film 128 to achieve better stress stretch flexibility and TIM film crack prevention.

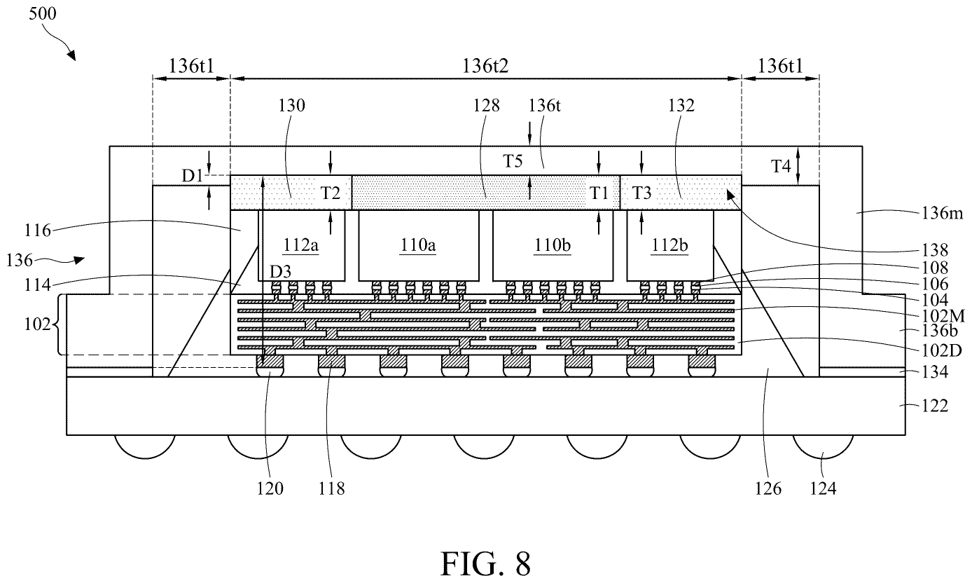

FIG. 8 illustrates a cross-sectional view of a semiconductor package structure 500 in accordance with some embodiments of the present disclosure. It should be noted that the semiconductor package structure 500 may include the same or similar components as those of the semiconductor package structure 100, which is illustrated in FIG. 1G, and for the sake of simplicity, those components will not be discussed in detail again. In the following embodiments, the thickness T1 of the TIM film 128 is increased.

As illustrated in FIG. 8, the thickness T1 of the TIM film 128 is increased, in accordance with some embodiments. The thickened TIM films 128, 130, and 132 may be disposed in the recess 138 and in the regions 136t2 of the heat-dissipating lid 136. The thickened TIM films 128, 130, and 132 may partially extend into the top portion 136t of the heat-dissipating lid 136. The top surfaces of the thickened TIM films 128, 130, and 132 may be substantially aligned with each other. The bottom surfaces of the thickened TIM films 128, 130, and 132 may be substantially aligned with each other.

The thickness T1 of the thickened TIM film 128 may be substantially equal to the thickness T2 of the thickened TIM film 130, and may be substantially equal to the thickness T3 of the thickened TIM film 132. Each of the thickness T1 of the thickened TIM film 128, the thickness T2 of the thickened TIM film 130, and the thickness T3 of the thickened TIM film 132 may be in a range of about 20 μm to about 300 μm. By increasing the thicknesses of the thickened TIM films 128, 130, and 132, the stress can be reduced. In addition, adopting separate TIM films instead of one TIM film can improve stress stretch flexibility and prevent crack propagation in the TIM film.

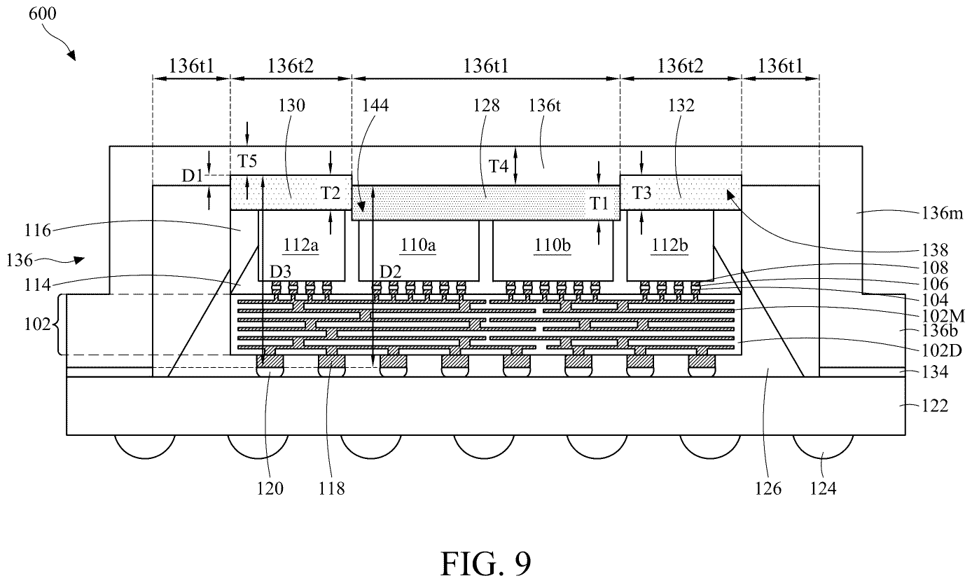

FIG. 9 illustrates a cross-sectional view of a semiconductor package structure 600 in accordance with some embodiments of the present disclosure. It should be noted that the semiconductor package structure 600 may include the same or similar components as those of the semiconductor package structure 100, which is illustrated in FIG. 1G, and for the sake of simplicity, those components will not be discussed in detail again. In the following embodiments, the TIM film 128 is disposed in a recess 144.

As illustrated in FIG. 9, the recess 144 is formed after forming the molding material 116 and before disposing the TIM film 128, in accordance with some embodiments. The recess 144 may be formed by using a photolithography process, an etching process, or another suitable process. The examples of the photolithography process and the etching process have been described above, and will not be repeated. The formation of the recess 144 may partially remove the semiconductor dies 110a, 110b, and the underfill material 114 (or the molding material 116 when the top surface of the underfill material 114 is lower than the top surfaces of the semiconductor dies 110a and 110b). The top surfaces of the semiconductor dies 110a and 110b may be lower than the top surfaces of the semiconductor dies 112a and 112b.

The semiconductor dies 112a and 112b may have a thickness T6, and the semiconductor dies 110a and 110b may have a thickness T7 in a direction that is substantially perpendicular to the top surface of the redistribution layer 102. The thickness T7 of one of the semiconductor dies 110a and 110b may be less than the thickness T6 of one of the semiconductor dies 112a and 112b. As a result, a shorter heat transfer path can be achieved.

In some embodiments, the thickness T7 of one of the semiconductor dies 110a and 110b is in a range of about 400 μm to about 800 μm. In some embodiments, the thickness T6 of one of the semiconductor dies 112a and 112b is in a range of about 500 μm to about 800 μm.

The TIM film 128 may be disposed in the recess 144 and may have a bottom surface below the bottom surfaces of thickened TIM films 130 and 132. Therefore, the thickness T1 of the TIM film 128 can be increased to reduce the stress. The thickness T1 of the TIM film 128 may be greater than, substantially equal to, or less than the thickness T2 of the thickened TIM film 130, and the thickness T3 of the thickened TIM film 132, depending on the depth of the recess 144.

As described previously, the semiconductor package substrate may include discrete TIM films 128, 130, 132, at least one of which has an increased thickness, so that the stress stretch flexibility can be improved and the crack propagation in the TIM films 128, 130, 132 can be prevented. In the embodiments illustrated in FIGS. 1G and 2, the TIM films 130 and 132 in periphery of the redistribution layer 102 are thickened. In the embodiments illustrated in FIG. 3, the interfaces between two of the TIM films 128, 130, 132, 140 and 142 are disposed directly above the gap between two of the semiconductor dies 110a, 110b, 112a, 112b, 112c, 112d, 112e, 112f, 112g, 112h, 112i, 112j to increase the efficiency of heat dissipation. In the embodiments illustrated in FIGS. 4 and 5, the TIM film 128 extends above the semiconductor dies 112a and 112b. In the embodiments illustrated in FIGS. 6 and 7, the thickened TIM films 130 and 132 extend above the semiconductor dies 110a and 110b. In the embodiments illustrated in FIG. 8, the thickness T1 of the TIM film 128 is increased. In the embodiments illustrated in FIG. 9, the thickness T7 of the semiconductor dies 110a and 110b is reduced for a shorter heat transfer path.

Embodiments of a semiconductor package structure and a method for forming the semiconductor package structure are provided. The semiconductor package structure includes individual pieces of TIM film which have different thicknesses corresponding to the location. Consequently, the stress stretch flexibility can be improved and the crack propagation in the TIM films can be prevented, and thus a better reliability performance especially in thermal cycle condition can be achieved.

In some embodiments, a semiconductor package structure is provided. The semiconductor package structure includes a redistribution layer attached to a substrate. The semiconductor package structure also includes a first semiconductor die and a second semiconductor die disposed over the redistribution layer. The semiconductor package structure also includes a first thermal interface material (TIM) film formed over the first semiconductor die. The semiconductor package structure also includes a second TIM film formed over the second semiconductor die. The semiconductor package structure also includes a heat-dissipating lid attached to the substrate. The heat-dissipating lid has first regions with a first cavity depth and a second region with a second cavity depth. The second cavity depth is greater than the first cavity depth. The second TIM film is disposed in the second region of the heat-dissipating lid.

In some embodiments, a semiconductor package structure is provided. The semiconductor package structure includes a first semiconductor die, a second semiconductor die, and a third semiconductor die disposed over a substrate. The first semiconductor die is between the second semiconductor die and the third semiconductor die. The semiconductor package structure also includes a first thermal interface material (TIM) film, a second TIM film, and a third TIM film formed over the first semiconductor die, the second semiconductor die, and the third semiconductor die, respectively. The semiconductor package structure also includes a heat-dissipating lid attached to the substrate. A top portion of the heat-dissipating lid has first regions with a first thickness and a second region with a second thickness that is less than the first thickness. The second TIM film and the third TIM film are disposed in the second region of the heat-dissipating lid.

In some embodiments, a method for forming a semiconductor package structure is provided. The method for forming the semiconductor package structure includes disposing a first semiconductor die and a second semiconductor die over a redistribution layer. The method for forming the semiconductor package structure also includes attaching the redistribution layer to a substrate. The method for forming the semiconductor package structure also includes attaching a first thermal interface material (TIM) film with a first thickness over the first semiconductor die. The method for forming the semiconductor package structure also includes attaching a second TIM film with a second thickness over the second semiconductor die. The method for forming the semiconductor package structure also includes attaching a heat-dissipating lid to the substrate. The heat-dissipating lid has a footing portion attached to the substrate and a board portion connected to the footing portion. The second TIM film partially extends into the board portion of the heat-dissipating lid.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package structure, comprising:
a redistribution layer attached to a substrate;
a first semiconductor die and a second semiconductor die disposed over the redistribution layer;
a first thermal interface material (TIM) film formed over the first semiconductor die;
a second TIM film formed over the second semiconductor die; and
a heat-dissipating lid attached to the substrate, wherein the heat-dissipating lid has first regions with a first cavity depth and a second region with a second cavity depth that is greater than the first cavity depth,
wherein the second TIM film is disposed in the second region of the heat-dissipating lid.

2. The semiconductor package structure as claimed in claim 1, wherein the first TIM film is disposed in the second region of the heat-dissipating lid.

3. The semiconductor package structure as claimed in claim 1, wherein the first TIM film is disposed in one of the first regions of the heat-dissipating lid.

4. The semiconductor package structure as claimed in claim 3, wherein a thickness of the second TIM film is greater than a thickness of the first TIM film.

5. The semiconductor package structure as claimed in claim 3, wherein the first TIM film extends below a top surface of the second semiconductor die.

6. The semiconductor package structure as claimed in claim 1, wherein the second TIM film extends over the first semiconductor die.

7. The semiconductor package structure as claimed in claim 1, wherein the first TIM film extends over the second semiconductor die.

8. A semiconductor package structure, comprising:
a first semiconductor die, a second semiconductor die, and a third semiconductor die disposed over a substrate, wherein the first semiconductor die is between the second semiconductor die and the third semiconductor die;
a first thermal interface material (TIM) film, a second TIM film, and a third TIM film formed over the first semiconductor die, the second semiconductor die, and the third semiconductor die, respectively; and
a heat-dissipating lid attached to the substrate, wherein a top portion of the heat-dissipating lid has first regions with a first thickness and a second region with a second thickness that is less than the first thickness,
wherein the second TIM film and the third TIM film are disposed in the second region of the heat-dissipating lid.

9. The semiconductor package structure as claimed in claim 8, wherein the second region is between the first regions.

10. The semiconductor package structure as claimed in claim 8, wherein the first regions of the heat-dissipating lid are on edges of the heat-dissipating lid.

11. The semiconductor package structure as claimed in claim 8, wherein the first TIM film is disposed in the second region of the heat-dissipating lid and has a thickness that is substantially equal to a thickness of the second TIM film and substantially equal to a thickness of the third TIM film.

12. The semiconductor package structure as claimed in claim 8, wherein the first TIM film is disposed in one of the first regions of the heat-dissipating lid and has a thickness that is less than a thickness of the second TIM film and less than a thickness of the third TIM film.

13. The semiconductor package structure as claimed in claim 8, wherein the first TIM film is disposed in a recess between the second semiconductor die and the third semiconductor die.

14. A method for forming a semiconductor package structure, comprising:
disposing a first semiconductor die and a second semiconductor die over a redistribution layer;
attaching the redistribution layer to a substrate;
attaching a first thermal interface material (TIM) film with a first thickness over the first semiconductor die;
attaching a second TIM film with a second thickness over the second semiconductor die; and
attaching a heat-dissipating lid to the substrate, wherein the heat-dissipating lid has a footing portion attached to the substrate and a board portion connected to the footing portion,
wherein the second TIM film partially extends into the board portion of the heat-dissipating lid.

15. The method for forming the semiconductor package structure as claimed in claim 14, further comprising:
forming a molding material over the redistribution layer and surrounding the first semiconductor die and the second semiconductor die before attaching the redistribution layer to the substrate,
wherein the second TIM film is in direct contact with the molding material.

16. The method for forming the semiconductor package structure as claimed in claim 15, further comprising partially removing the first semiconductor die after forming the molding material.

17. The method for forming the semiconductor package structure as claimed in claim 14, wherein the first TIM film and the second TIM film are formed of a solid material.

18. The method for forming the semiconductor package structure as claimed in claim 14, wherein the first thickness is substantially equal to the second thickness.

19. The method for forming the semiconductor package structure as claimed in claim 14, wherein the second thickness is greater than the first thickness.

20. The method for forming the semiconductor package structure as claimed in claim 14, wherein the second TIM film surrounds the first TIM film when viewed in a top view.
